(19) United States
(12) Patent Application Publication
(10) Pub. No.: US 2024/0209491 A1
(43) Pub. Date: Jun. 27, 2024

(54) POWER LIMITER WITH WAVEGUIDE HAVING AN LaCoO3 FILM

(71) Applicant: NORTHROP GRUMMAN SYSTEMS CORPORATION, FALLS CHURCH, VA (US)

(72) Inventors: Rajashree Bhattacharya, San Jose, CA (US); Vincent Gambin, Rancho Palos Verdes, CA (US)

(21) Appl. No.: 18/597,354

(22) Filed: Mar. 6, 2024

Related U.S. Application Data
(62) Division of application No. 17/318,519, filed on May 12, 2021.

(51) Int. Cl. C23C 14/08; C23C 14/34; C23C 14/50; C23C 14/58; H01J 37/34

(52) U.S. Cl. CPC C23C 14/08; C23C 14/3464; C23C 14/505; C23C 14/5806; H01J 37/3426

(57) ABSTRACT

A power limiter for limiting power provided to an electronic device. The power limiter includes a waveguide that receives an input signal to be sent to the electronic device, an LaCoO₃ film formed to one side of the waveguide, an LaCoO₃ film formed to an opposite side of the waveguide, a grounded element formed to one of the LaCoO₃ films and a grounded element formed to the other LaCoO₃ film. When the heat level in the LaCoO₃ films is below a predetermined threshold, the LaCoO₃ films are an insulator and the input signal propagates through the waveguide to the electronic device, and when the heat level in the LaCoO₃ films goes above the threshold, the LaCoO₃ films become conductive, and the input signal is shunted through the LaCoO₃ films to the grounded elements.

### CROSS REFERENCE TO RELATED APPLICATIONS

This application is a divisional application of co-pending U.S. application Ser. No. 17/318,519, titled, LaCoO3 Thin Film Deposition by DC Metal Co-Sputtering, filed May 12, 2021.

### BACKGROUND

### Field

This disclosure relates generally to a power limiter and, more particularly, to a power limiter including a waveguide having an LaCoO₃ film formed thereto.

### Discussion of the Related Art

RF power limiters are often employed in receiver front end circuits and other devices to protect sensitive electrical components, such as low noise amplifiers (LNA), from high power RF signals. Traditionally these power limiters are solid-state devices that employ semiconductor components, such as p-i-n diodes or MESFET devices, that limit input power for a certain frequency range. However, with the advance of power and agility in RF components and systems additional challenges in the form of low power consumption, higher incident power control and high reliability are placed on traditional RF power limiters. These challenges have led to the investigation of new power limiting materials that often employ an insulator-to-metal phase transition (IMT) in response to a certain temperature change that improve with increasing power. In response to increasing current, and thus temperature, an IMT material will transition from an insulative state to a metallic state, which shunts power above a given threshold.

One IMT material that can demonstrate IMT behavior for power limiting purposes is vanadium dioxide (VO₂). VO₂ has been synthesized by a wide variety of methods, such as molecular beam epitaxy (MBE), pulsed laser deposition and direct current and radio frequency sputtering. VO₂ provides a sharp drop in resistance as the material heats to around 340 degrees Kelvin. However, this temperature is generally too low for practical device operation for many systems.

Another IMT material that can demonstrate IMT behavior is lanthanum cobalt oxide (LaCoO₃). LaCoO₃ has an IMT at a higher temperature than other IMT materials such as VO₂. More particularly, LaCoO₃ exhibits a large reduction in resistivity at around 500 degrees Kelvin as a result of a non-structural phase transition, such as electronic spin state transition or orbital melting mechanism, that provides a rapid electrical resistivity drop as a function of increasing temperature. Typical methods of synthesis for LaCoO₃ found in the literature focus on the production of porous volumes because the majority of research on the material is in its application for catalysis for gas sensors and humidity sensors. Various processes have been reported in the literature for depositing thin films of LaCoO₃ that typically focus on catalytic applications, which include MBE, ion beam sputtering, chemical vapor deposition and pulsed laser deposition. MBE is known to produce high quality, smooth, crystalline films. However, it is a slow, difficult and an expensive process. The literature shows that films of LaCoO₃ can be produced using DC co-sputtering of metal targets, but those processes required post-deposition calcination steps to properly oxygenate and crystallize the films.

### BRIEF DESCRIPTION OF THE DRAWINGS

FIG. 1 is a schematic block diagram of a power limiter employing an LaCoO₃ film; and

FIG. 2 is a schematic block diagram of a sputtering system for producing an LaCoO₃ film.

### DETAILED DESCRIPTION OF THE EMBODIMENTS

The following discussion of the embodiments of the disclosure directed to a power limiter including a waveguide having an LaCoO₃ film formed thereto is merely exemplary in nature, and is in no way intended to limit the disclosure or its applications or uses.

This disclosure proposes producing RF devices that employ an LaCoO₃ film that provide a quick drop in resistance as temperature increases above a threshold. The challenge is to produce smooth, high quality crystalline thin LaCoO₃ films having a high insulator-to-metal transition point on various substrates that is relatively low cost, amenable to large scale production. It should also consist of only one step for simplicity and to protect underlying device layers from damage in high temperature calcination. The process will be able to deposit the LaCoO₃ films onto a variety of substrates with varying dielectric properties in order to optimize the film properties and device performance.

In order to provide an RF device as described above, this disclosure describes a single step DC sputtering process for synthesis of LaCoO₃ using relatively cheap source materials that can quickly produce large wafer scale material. Rather than use a ceramic target of pre-sintered LaCoO₃, the proposed process utilizes cheaper metal targets of lanthanum and cobalt. The process uses a heated substrate in conjunction with deposition of the metal targets in a reactive oxygen/argon atmosphere. These metals are vaporized by a direct current magnetron gun that ejects material toward the substrate. Under these conditions, the metals react and crystallize directly onto the substrate surface to form the LaCoO₃ film. Thus, no secondary processing steps are required to fully crystallize or oxygenate the film. An additional advantage of the proposed process is that using independently controlled metal targets allows for tuning of the composition of the film, affording greater control over optimization of the film properties. The ability to vary the substrate temperature with this process also allows for balancing the benefits between highly crystalline films grown at 700° C. and the amorphous films grown at low temperatures. Furthermore, while still able to produce smooth, quality films, sputtering is considered a low cost and fast production tool used for large wafer scale synthesis.

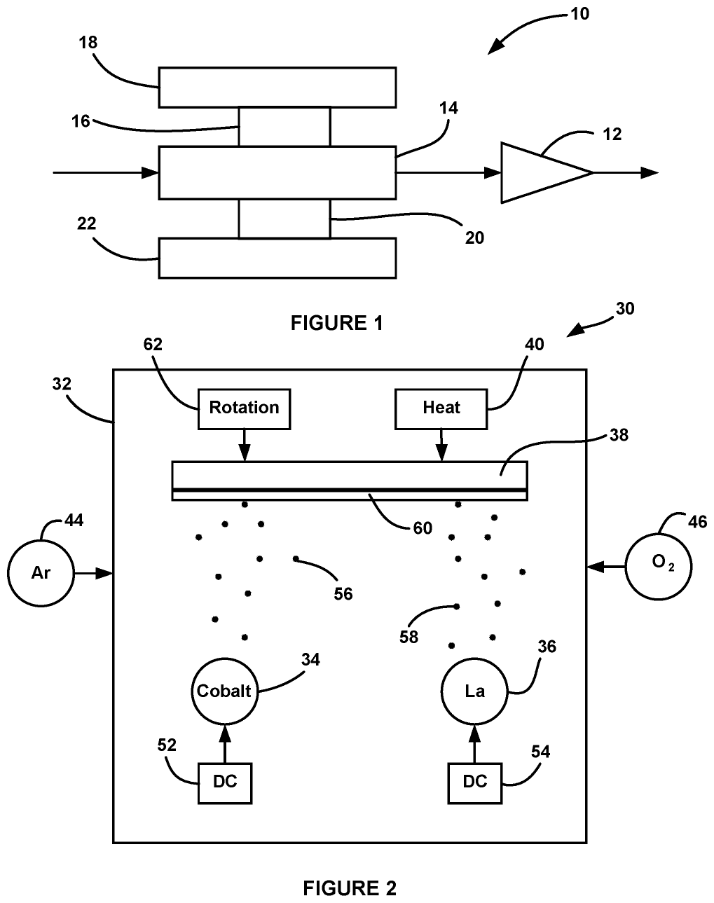

FIG. 1 is a schematic block diagram of a power limiter 10 that limits the amount of power that can be delivered to a sensitive electrical device 12, such as an LNA. An input signal is provided to a waveguide 14 that delivers the signal to the device 12. An LaCoO₃ film 16 is formed on one side of the waveguide 14 and is coupled to a grounded element 18 and an LaCoO₃ film 20 is formed on an opposite side of the waveguide 14 and is coupled to a grounded element 22. As the power of the input signal increases more heat is generated in the films 16 and 20. When the heat level in the films 16 and 20 is below a certain threshold, the films 16 and 20 are an insulator and the signal propagates straight through the waveguide 14 to the device 12. When the heat level in the films 16 and 20 reaches the threshold, the films 16 and 20 transition to a metal and become conductive, and power in the signal is shunted through the films 16 and 20 to the grounded elements 18 and 22, and minimal power is transmitted to the device 12. When the heat level in the films 16 and 20 falls below the threshold, the films 16 and 20 transition back to an insulator.

FIG. 2 is a schematic block diagram of a sputter system 30 including a vacuum chamber 32. A cobalt source target 34 and a lanthanum source target 36 are positioned with the chamber 32 relative to a substrate 38, where the substrate 38 is intended to represent any substrate of a suitable material, such as silicon carbide, sapphire, fused silica, silicon, lanthanum aluminate, etc., or a fully fabricated device, such as a GaN wafer. Depending on the application, the substrate 38 May be heated by a heater 40 to a desired temperature, for example, between 400° C. and 700° C. to enhance the sputtering process. An argon or other suitable inert gas from a source 44 and oxygen from a source 46 are emitted into the chamber 32, which increases the pressure in the chamber 32 to, for example, 5 mtorr.

A negative bias potential is applied to the targets 34 and 36 by DC sources 52 and 54, respectively. Magnets (not shown) are employed to increase the ionization frequency by trapping a cloud of electrons near the surface of the targets 34 and 36, which increases the likelihood of collision and ionization of the argon gas. Positive argon ions bombard the targets 34 and 36, which releases cobalt atoms 56 from the target 34 and lanthanum atoms 58 from the target 36. The atoms 56 and 58 are drawn to the substrate 38 where they react directly with the oxygen to create a crystalized LaCoO₃ film 60 on the substrate 38. A rotation device 62 rotates the substrate 38 so that the film 60 has a uniform concentration of cobalt and lanthanum. The sputtering process is continued until the thickness of the film 60 reaches a desired thickness, for example, 40-200 nm. The percentage of oxygen in the chamber 32 is carefully tuned to avoid significant oxidization of the targets 34 and 36.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A power limiter for limiting power applied to an electronic device, said power limiter comprising:
a waveguide that receives an input signal to be sent to the electronic device;
at least one LaCoO₃ film formed to the waveguide; and
at least one grounded element formed to the at least one LaCoO₃ film opposite to the waveguide, wherein the at least one LaCoO₃ film is configured so that when a heat level in the at least one LaCoO₃ film is below a predetermined threshold, the at least one LaCoO₃ film is an insulator and the input signal propagates through the waveguide to the electronic device, and when the heat level in the at least one LaCoO₃ film is above the threshold, the at least one LaCoO₃ film becomes conductive, and the input signal is shunted through the at least one LaCoO₃ film to the at least one grounded element.

2. The power limiter according to claim 1 wherein the at least one LaCoO₃ film is a first LaCoO₃ film formed to one side of the waveguide and a second LaCoO₃ film formed to an opposite side of the waveguide, and wherein the at least one grounded element is a fist grounded element formed to the first LaCoO₃ film and a second grounded element formed to the second LaCoO₃ film.

3. The power limiter according to claim 1 wherein the at least one LaCoO₃ film has a thickness between 40 and 200 nm.

4. The power limiter according to claim 1 wherein the electronic device is a low noise amplifier (LNA).

5. The power limiter according to claim 1 wherein the power limiter is configured such that the at least one LaCoO₃ film is formed to the waveguide by positioning the waveguide in a vacuum chamber, positioning a cobalt target in the vacuum chamber, positioning a lanthanum target in the vacuum chamber, providing oxygen in the vacuum chamber, and sputtering cobalt atoms off of the cobalt target and lanthanum atoms off of the lanthanum target so that the cobalt and lanthanum atoms interact with the oxygen to form the LaCoO₃ film on the waveguide.

6. The power limiter according to claim 5 wherein the waveguide is heated when the at least one LaCoO₃ film is being formed thereto.

7. The power limiter according to claim 6 wherein heating the waveguide includes heating the waveguide to a temperature between 400° C. and 700° C.

8. The power limiter according to claim 5 wherein the waveguide is rotated when the at least one LaCoO₃ film is being formed thereto.

9. The power limiter according to claim 5 wherein sputtering cobalt and lanthanum atoms includes generating an inert gas plasma in the chamber and biasing the cobalt and lanthanum targets so that plasma ions bombard the targets.

10. The power limiter according to claim 9 wherein the inert gas is argon.

11. A power limiter for limiting power applied to a low noise amplifier (LNA), said power limiter comprising:
a waveguide that receives an input signal to be sent to the LNA;
a first LaCoO₃ film formed to one side of the waveguide and a second LaCoO₃ film formed to an opposite side of the waveguide; and
a fist grounded element formed to the first LaCoO₃ film opposite to the waveguide and a second grounded element formed to the second LaCoO₃ film opposite to the waveguide, wherein the first and second LaCoO₃ films are configured so that when a heat level in the first and second LaCoO₃ films is below a predetermined threshold, the first and second LaCoO₃ films are an insulator and the input signal propagates through the waveguide to the LNA, and when the heat level in the first and second LaCoO₃ films is above the threshold, the first and second LaCoO₃ films become conductive, and the input signal is shunted through the first and second LaCoO₃ films to the first and second grounded elements.

12. The power limiter according to claim 11 wherein the first and second LaCoO₃ films have a thickness between 40 and 200 nm.

13. The power limiter according to claim 11 wherein the power limiter is configured such that the first and second LaCoO₃ films are formed to the waveguide by positioning the waveguide in a vacuum chamber, positioning a cobalt target in the vacuum chamber, positioning a lanthanum target in the vacuum chamber, providing oxygen in the vacuum chamber, and sputtering cobalt atoms off of the cobalt target and lanthanum atoms off of the lanthanum target so that the cobalt and lanthanum atoms interact with the oxygen to form the first and second LaCoO₃ films on the waveguide.

14. The power limiter according to claim 13 wherein the waveguide is heated when the first and second LaCoO₃ films are being formed thereto.

15. The power limiter according to claim 14 wherein heating the waveguide includes heating the waveguide to a temperature between 400° C. and 700° C.

16. The power limiter according to claim 13 wherein sputtering cobalt and lanthanum atoms includes generating an inert gas plasma in the chamber and biasing the cobalt and lanthanum targets so that plasma ions bombard the targets.

17. A method for controlling power applied to an electronic device, said method comprising:
providing a power limiter that includes a waveguide, at least one LaCoO₃ film formed to the waveguide, and at least one grounded element formed to the at least one LaCoO₃ film opposite to the waveguide, wherein the at least one LaCoO₃ film is configured to operate as an insulator when a heat level of the at least one LaCoO₃ film is below a predetermined threshold and to operate as conductor when the heat level of the at least one LaCoO₃ film is above the threshold;
providing an input signal to the electronic device through the waveguide when the heat level of the at least one LaCoO₃ film is below the threshold; and
shunting the input signal through the at least one LaCoO₃ film to the at least one grounded element when the heat level of the at least one LaCoO₃ film is above the threshold.

18. The method according to claim 17 wherein the at least one LaCoO₃ film is a first LaCoO₃ film formed to one side of the waveguide and a second LaCoO₃ film formed to an opposite side of the waveguide, and wherein the at least one grounded element is a fist grounded element formed to the first LaCoO₃ film and a second grounded element formed to the second LaCoO₃ film.

19. The method according to claim 17 wherein the at least one LaCoO₃ film has a thickness between 40 and 200 nm.

20. The method according to claim 17 wherein the electronic device is a low noise amplifier (LNA).
